(19) United States
(12) Patent Application Publication
(10) Pub. No.: US 2007/0096777 A1
(43) Pub. Date: May 3, 2007

(54) Differential driver

(76) Inventors: Dacheng Zhou, Fort Collins, CO (US); Yu-Ming Chiang, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/265,690

(22) Filed: Nov. 1, 2005

(51) Int. Cl. H03B 1/00

(52) U.S. Cl. 327/108

(57) ABSTRACT

A differential driver includes first and second switches connected in parallel to a current source, with a pair of differential inputs connected to control inputs on the first and second switches, and first and second output drivers connected to the first and second switches through current mirrors.

### BACKGROUND

Differential drivers may be used in electronic circuits to drive a differential electrical signal across a transmission line to a receiver. A typical differential driver includes a constant current supply generated by a field effect transistor operating in the saturation region. However, as modern integrated circuits are becoming increasingly miniaturized, the supply voltages are continuing to drop. It is therefore difficult to keep field effect transistors in a differential driver operating in the saturation region without reducing the output swing from the differential driver to undesirably small levels.

### SUMMARY

An exemplary differential driver includes first and second switches connected in parallel to a current source, with a pair of differential inputs connected to control inputs on the first and second switches, and first and second output drivers connected to the first and second switches through current mirrors.

### BRIEF DESCRIPTION OF THE DRAWINGS

Illustrative embodiments are shown in the accompanying drawings as described below.

FIG. 1 is a block diagram illustrating an exemplary differential driver having an output swing referenced to a termination voltage.

FIG. 2 is a block diagram illustrating another exemplary differential driver having an output swing referenced to ground.

FIG. 3 is a block diagram illustrating an exemplary differential driver that is connected to a receiver using DC coupling.

FIG. 4 is a block diagram illustrating another exemplary differential driver that is connected to a receiver using AC coupling.

FIG. 5 is a flow chart illustrating an exemplary operation for driving a differential signal on a transmission line.

### DESCRIPTION

The drawings and description, in general, disclose a differential driver circuit for driving a differential signal on a transmission line. A current source is provided in the differential driver outside of the output drivers, such as in the pre-driver, so that it does not reduce the output swing of the output drivers. Placing the current source outside the output drivers rather than inline in the output drivers also removes the parasitic capacitive loading of the current source from the output drivers, effectively improving the signal edge rate and driver return-loss characteristics.

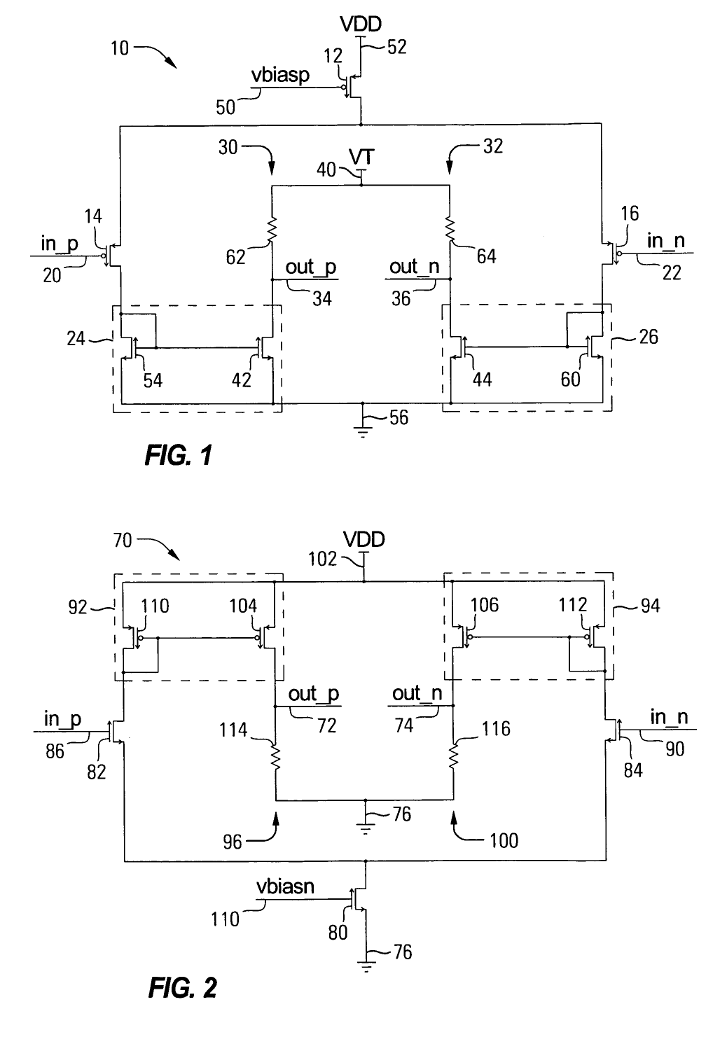

A first exemplary embodiment of a differential driver 10 is illustrated in FIG. 1. A p-channel field effect transistor (PFET) 12 is used in the exemplary embodiment to supply a constant tail current for the differential driver 10, although the differential driver 10 may employ other types of constant current sources. The tail current is steered to one side or the other of the differential driver 10 by steering switches 14 and 16, controlled by the differential inputs 20 and 22. A pair of current mirrors 24 and 26 mirror the tail current to the output drivers 30 and 32, providing a signal voltage swing to the output drivers 30 and 32 with the swing level based on the level of the tail current. Because the current source 12 is outside the output drivers 30 and 32, the voltage swing of the differential outputs 34 and 36 is dependent only upon the termination voltage VT 40 and the voltage drop across the output FETS 42 and 44 in the current mirrors 24 and 26, and not upon the voltage drop across the current source 12.

A bias voltage vbiasp 50 is applied to the gate of the current source FET 12, and a voltage supply VDD 52 is applied to the source of the current source FET 12. As discussed above, the current source FET 12 is operated in the saturation region in order to provide a constant current. The term “saturation” refers herein to an operating region in which for a PFET, Vds<Vgs−Vth, where Vds is the drain-source voltage, Vgs is the gate-source voltage, and Vth is the threshold voltage. For example, consider the case in which VDD 52 is 1.2 volts, the threshold voltage Vth for the current source FET 12 is −0.25 volts, and the drain voltage is 0.9 volts. Vds is therefore 0.9−1.2 or −0.3 volts, so the equation above is −0.3v<Vgs−(−0.25v) so Vgs should be greater than −0.55 volts. Therefore, Vbiasp −1.2v>−0.55v so Vbiasp should be greater than 0.65 volts.

The steering switches 14 and 16 may each comprise a PFET, having the sources both connected to the drain of the current source FET 12. A first differential input in_p 20 is connected to the gate of one of the steering FETS 14, and a second differential input in_n 22 is connected to the gate of the other steering FET 16.

The exemplary current mirrors 24 and 26 each comprise a pair of n-channel field effect transistors (NFETS) operating in the saturation region. Referring now to the first current mirror 24, the reference FET 54 is forced into the saturation region and is operated as a diode by connecting the drain and gate. The reference FET 54 carries the tail current as a reference current. The gate of the reference FET 54 is also connected to the gate of the output FET 42, ensuring identical control voltages Vgs at the gates of the current mirror FETS 54 and 42. The identical control voltages cause the tail current through the reference FET 54 to be mirrored to the output FET 42, with identical current levels if the reference and output FETS 54 and 42 are physically matched. Alternatively, the current through the output FET 42 may be mirrored at other desired fixed ratios by altering the dimensions of the reference and output FETS 54 and 42. The sources of the reference and output FETS 54 and 42 are connected to a ground 56. The first current mirror 24 is connected to the first steering switch 14 by connecting the drain of the reference FET 54 to the drain of the steering FET 14.

The second current mirror operates in the same fashion and includes a reference FET 60 and an output FET 44. The gate and drain of the reference FET 60 are connected to the gate of the output FET 44. The sources of the reference and output FETS 60 and 44 are connected to a ground 56. The second current mirror 26 is connected to the second steering switch 16 by connecting the drain of the reference FET 60 to the drain of the steering FET 16.

The output drivers 30 and 32 each comprise a resistor 62 and 64 connected to a termination voltage source VT 40. The output driver resistors 62 and 64 provide resistive loads to match the impedance of an external transmission line. The impedance or resistance of the output driver resistors 62 and 64 is selected to reduce signal reflection on the transmission line. The output drivers 30 and 32 are connected to the current mirrors 24 and 26 so that the mirrored tail current is pulled through the output drivers 30 and 32. For example, a first end of the resistor 62 in the first output driver 30 is connected to the termination voltage VT 40, and a second end of the resistor 62 is connected to the drain of the output FET 42 in the first current mirror 24. The first differential output out_p 34 is connected to the second end of the resistor 62 and the drain of the output FET 42 in the first current mirror 24. Similarly, the first end of the resistor 64 in the second output driver 32 is connected to the termination voltage VT 40, and a second end of the resistor 64 is connected to the drain of the output FET 44 in the second current mirror 26. The second differential output out_n 36 is connected to the second end of the resistor 64 and the drain of the output FET 44 in the second current mirror 26.

Note that in the exemplary embodiment, the supply voltage VDD 52 and the termination voltage VT 40 are set at the same voltage level, such as 1.2 volts. However, the supply voltage VDD 52 and the termination voltage VT 40 may be set at different voltage levels.

In the exemplary embodiment illustrated in FIG. 1, the voltage swing in the differential outputs 34 and 36 is referenced to the termination voltage VT 40. During operation, one of the differential inputs (e.g., 20) will typically be asserted (high) while the other (e.g., 22) is unasserted (low). The first steering switch 14 will therefore be off and the second steering switch 16 will be on, steering the tail current from the current source 12 to the second current mirror 26. The current through the first current mirror 24 and the first output driver 30 will therefore be substantially zero, while the current through the second current mirror 26 and the second output driver 32 will therefore be substantially equal to the tail current. Because no current passes through the output FET 42 of the first current mirror 24, the first output driver 30 is isolated from the ground 56, and the first differential output out_p 34 will be pulled up (asserted) to the termination voltage VT 40 through the resistor 62. The tail current will pass through the output FET 44 of the second current mirror 26, pulling the second differential output out_n 36 down to an unasserted level. This level may be adjusted by the tail current level and the resistance of the output resistors 62 and 64 based on the voltage headroom provided by the termination voltage VT 40. For example, if the tail current is 10 milliamps and the output resistors 62 and 64 are each 50 ohms, the voltage drop across the output resistors 62 and 64 will be 500 millivolts. Thus, for a termination voltage VT 40 of 1.2 volts, the asserted voltage level of the differential outputs 62 and 64 will be about 1.2 volts, and the unasserted voltage level will be about 1.2−0.5 or 0.7 volts. In summary, when the first input in_p 20 is asserted and the second input in_n 22 is not asserted, the first output out_p 34 will be asserted (high) and the second output out_n 36 will not be asserted (low). When the first input in_p 20 is not asserted and the second input in_n 22 is asserted, the first output out_p 34 will not be asserted (low) and the second output out_n 36 will be asserted (high).

Another exemplary embodiment 70 is illustrated in FIG. 2. In this exemplary embodiment, the voltage swing in the differential outputs 72 and 74 is referenced to ground 76 rather than to a termination voltage VT as in the first embodiment of FIG. 1. A tail current source 80 provides a constant current to generate a predetermined voltage swing in the differential outputs 72 and 74. An NFET 80 is used in the exemplary embodiment to supply a constant tail current for the differential driver 70, although as discussed above, the differential driver 70 may employ other types of constant current sources. The tail current is steered to one side or the other of the differential driver 70 by steering switches 82 and 84, controlled by the differential inputs 86 and 90. A pair of current mirrors 92 and 94 mirror the tail current to the output drivers 96 and 100, providing a signal voltage swing to the output driver 96 and 100 with swing level based on the level of the tail current. Because the current source 80 is outside the output drivers 96 and 100, the voltage swing of the differential outputs 72 and 74 is dependent only upon the voltage supply VDD 102 and the voltage drop across the output FETS 104 and 106 in the current mirrors 92 and 94, and not upon the voltage drop across the current source 80.

A bias voltage vbiasn 110 is applied to the gate of the current source FET 80, and the source of the current source FET 80 is grounded. As discussed above, the current source FET 80 is operated in the saturation region in order to provide a constant current. The steering switches 82 and 84 are connected to the current source FET 80 to direct the tail current to one side or the other of the differential driver 70 according to the differential inputs 86 and 90. In this exemplary embodiment, the steering switches 82 and 84 each comprise an NFET, having the sources both connected to the drain of the current source FET 80. The first differential input in_p 86 is connected to the gate of one of the steering FETS 82, and a second differential input in_n 90 is connected to the gate of the other steering FET 84.

The exemplary current mirrors 92 and 94 each comprise a pair of PFETS operating in the saturation region, wherein the drain and gate of the reference FETS 110 and 112 are connected to the gate of the associated output FETS 104 and 106. The sources of the reference and output FETS 110, 112, 104 and 106 in both current mirrors 92 and 94 are connected to the voltage supply VDD 102. The drains of the reference FETS 110 and 112 are connected to the drains of the steering FETS 82 and 84. The current mirrors operate as described above with respect to FIG. 1, so that the tail current from the current source 80 is mirrored into the output drivers 96 and 100.

The output drivers 96 and 100 each comprise a resistor 114 and 116 connected to a ground 76. The output driver resistors 114 and 116 provide resistive loads to match the impedance of an external transmission line. The impedance or resistance of the output driver resistors 114 and 116 is selected to reduce signal reflection on the transmission line. The output drivers 114 and 116 are connected to the current mirrors 92 and 94 so that the mirrored tail current is pulled through the output drivers 96 and 100. For example, a first end of the resistor 114 in the first output driver 96 is connected to ground 76, and a second end of the resistor 114 is connected to the drain of the output FET 104 in the first current mirror 92. The first differential output out_p 72 is connected to the second end of the resistor 114 and the drain of the output FET 104 in the first current mirror 92. Similarly, the first end of the resistor 116 in the second output driver 100 is connected to ground 76, and a second end of the resistor 116 is connected to the drain of the output FET 106 in the second current mirror 94. The second differential output out_n 74 is connected to the second end of the resistor 116 and the drain of the output FET 106 in the second current mirror 94.

In the exemplary embodiment illustrated in FIG. 2, the voltage swing in the differential outputs 114 and 116 is referenced to ground 76. During operation, one of the differential inputs (e.g., 86) will typically be asserted (high) while the other (e.g., 90) is unasserted (low). The first steering switch 82 will therefore be on and the second steering switch 84 will be off, steering the tail current from the current source 80 to the first current mirror 92. The current through the first current mirror 92 and the first output driver 96 will therefore be substantially equal to the tail current, while the current through the second current mirror 94 and the second output driver 100 will therefore be substantially zero. Because no current passes through the output FET 106 of the second current mirror 94, the second output driver 100 is isolated from the voltage supply VDD 102, and the second differential output out_n 74 will be pulled down (unasserted) to ground through the resistor 116. The tail current will pass through the output FET 104 of the first current mirror 92, pulling the first differential output out_p 72 up to an asserted level. This level may be adjusted by the tail current level and the resistance of the output resistors 114 and 116 based on the voltage headroom provided by the voltage supply VDD 102. For example, if the tail current is 10 milliamps and the output resistors 114 and 116 are each 50 ohms, the voltage drop across the output resistors 114 and 116 will be 500 millivolts. Thus, for a voltage supply VDD 102 of 1.2 volts, the asserted voltage level of the differential outputs 72 and 74 will be about 0.5 volts and the unasserted voltage level will be about zero volts. In summary, when the first input in_p 86 is asserted and the second input in_n 90 is not asserted, the first output out_p 72 will be asserted (high) and the second output out_n 74 will not be asserted (low). When the first input in_p 86 is not asserted and the second input in_n 90 is asserted, the first output out_p 72 will not be asserted (low) and the second output out_n 74 will be asserted (high).

In an alternative embodiment, the pre-driver portions of the exemplary circuits 10 and 70 illustrated in FIGS. 1 and 2, including the current source 12 and 80 and current mirrors 24, 26, 92 and 94, may be replaced with any suitable circuitry that keeps the final driver FETS 42, 44, 104 and 106 in the saturation regions and that selectively triggers the current in the output drivers 30, 32, 96 and 100 according to the differential inputs 20, 22, 86 and 90.

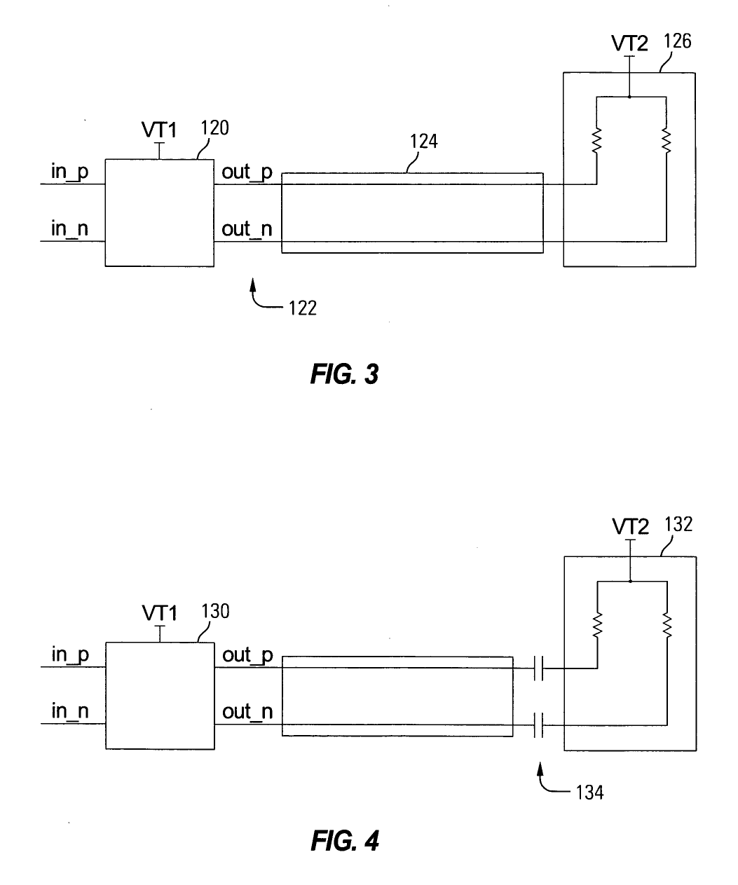

The differential driver (e.g., 10, 70) may be connected to a receiver in any suitable manner desired, such as direct-current (DC) coupling as illustrated in FIG. 3 or alternating-current (AC) coupling as illustrated in FIG. 4. The differential driver 120 (FIG. 3) drives signals on the differential outputs 122 across a transmission line 124, such as conductive traces on a printed circuit board, to a receiver 126. When using DC coupling, the voltage swing in the differential driver 120 and receiver 126 should be referenced the same way, either to ground or to a termination voltage VT, to prevent interoperability problems. However, if the voltage swings in the differential driver 130 (FIG. 4) and receiver 132 have different references, AC coupling may be used by placing capacitors 134 between the differential driver 130 and receiver 132. For example, if the voltage swing in the differential driver 130 is referenced to ground as discussed above with respect to FIG. 2, but is referenced to a termination voltage VT in the receiver 132, the capacitors 134 filter out the differing dc bias between the differential driver 130 and receiver 132. Note that AC coupling may require a higher headroom between ground and a voltage supply in the differential driver 130 to maintain an acceptable voltage swing.

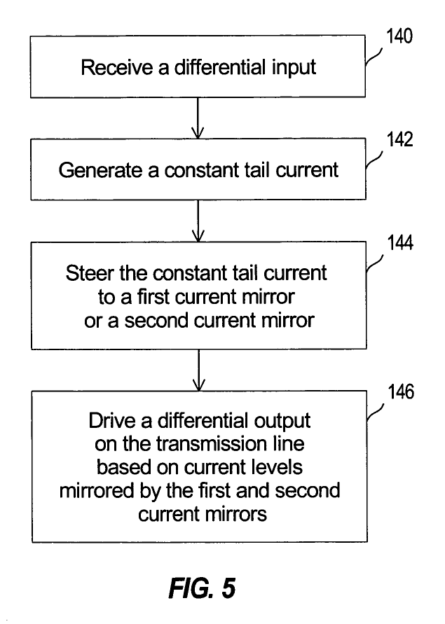

An exemplary operation for driving a differential signal on a transmission line is illustrated in the flowchart of FIG. 5. The exemplary operation includes receiving 140 a differential input, generating 142 a constant tail current, steering 144 the constant tail current to a first current mirror or a second current mirror, and driving 146 a differential output on the transmission line based on current levels mirrored by the first and second current mirrors. As discussed above, the voltage swing on the differential output may reference any desired voltage level, such as ground or a termination voltage.

While illustrative embodiments have been described in detail herein, it is to be understood that the concepts disclosed herein may be otherwise variously embodied and employed, and that the appended claims are intended to be construed to include such variations, except as limited by the prior art.

What is claimed is:

1. A differential driver, comprising:
a current source;
a first switch and a second switch connected in parallel to said current source;
a first differential input connected to a control input on said first switch and a second differential input connected to a control input on said second switch;
a first output driver connected to said first switch through a first current mirror; and
a second output driver connected to said second switch through a second current mirror.

2. The differential driver of claim 1, said current source comprising a field effect transistor operating in a saturation region.

3. The differential driver of claim 2, said current source comprising a constant current source for generating a tail current.

4. The differential driver of claim 2, said current source field effect transistor comprising a p-channel field effect transistor, said current source further comprising a voltage supply connected to a source of said current source field effect transistor, wherein said first and second switches are each connected to a drain of said current source field effect transistor.

5. The differential driver of claim 1, said first and second switches each comprising a p-channel field effect transistor having a source connected to said current source, wherein said control inputs comprise a gate of said p-channel field effect transistors, and wherein said p-channel field effect transistors are connected to said first and second current mirrors by a drain on each of said p-channel field effect transistors.

6. The differential driver of claim 1, said first and second current mirrors each comprising a reference n-channel field effect transistor and an output n-channel field effect transistor, each having a source connected to a ground, wherein a drain and a gate of said reference n-channel field effect transistor are connected to a gate of said output n-channel field effect transistor, and wherein said first and second current mirrors are connected to said first and second switches at said drains of said reference n-channel field effect transistors.

7. The differential driver of claim 6, said first output driver comprising a resistor connected at a first node to a voltage supply and at a second node to a drain of said first current mirror output n-channel field effect transistor, wherein a first output of said differential driver is connected to said second node of said first output driver, said second output driver comprising a resistor connected at a first node to said voltage supply and at a second node to said drain of said second current mirror output n-channel field effect transistor, wherein a second output of said differential driver is connected to said second node of said second output driver.

8. The differential driver of claim 2, said current source field effect transistor comprising an n-channel field effect transistor having a source connected to a ground, wherein said first and second switches are each connected to a drain of said current source field effect transistor.

9. The differential driver of claim 1, said first and second switches each comprising an n-channel field effect transistor having a source connected to said current source, wherein said control inputs comprise a gate of said n-channel field effect transistors, and wherein said n-channel field effect transistors are connected to said first and second current mirrors by a drain on each of said n-channel field effect transistors.

10. The differential driver of claim 1, said first and second current mirrors each comprising a reference p-channel field effect transistor and an output p-channel field effect transistor, each having a source connected to a voltage supply, wherein a drain and a gate of said reference p-channel field effect transistor are connected to a gate of said output p-channel field effect transistor, and wherein said first and second current mirrors are connected to said first and second switches at said drains of said reference p-channel field effect transistors.

11. The differential driver of claim 10, said first output driver comprising a resistor connected at a first node to a ground and at a second node to a drain of said first current mirror output p-channel field effect transistor, wherein a first output of said differential driver is connected to said second node of said first output driver, said second output driver comprising a resistor connected at a first node to said ground and at a second node to a drain of said second current mirror output p-channel field effect transistor, wherein a second output of said differential driver is connected to said second node of said second output driver.

12. A method of driving a differential signal on a transmission line, comprising:
receiving a differential input;
generating a constant tail current;
steering said constant tail current to a first current mirror or a second current mirror; and
driving a differential output on said transmission line based on current levels mirrored by said first and second current mirrors.

13. The method of claim 12, wherein said generating said constant tail current comprises operating a field effect transistor in a saturated operating range.

14. The method of claim 12, wherein a voltage swing in said differential output is referenced to a ground.

15. The method of claim 12, wherein a voltage swing in said differential output is referenced to a reference voltage level.

16. A differential driver comprising a pair of output drivers, each of said pair of output drivers consisting essentially of a resistor and a transistor operating in a saturation region, said resistor and said transistor being connected between a power supply and a ground, wherein current through said pair of transistors is controlled by a pair of differential inputs.

17. A differential driver circuit for driving signals on a transmission line, comprising:
means for driving a differential signal;
means for generating a constant electrical current outside of said means for driving said differential signal; and
means for copying said constant electrical current into said means for driving said differential signal.
